(19) United States
(12) Patent Application Publication
(10) Pub. No.: US 2024/0379868 A1
(43) Pub. Date: Nov. 14, 2024

(54) THIN FILM TRANSISTOR AND MANUFACTURING METHOD FOR THE SAME

(71) Applicant: ADRC. CO. KR, Seoul (KR)

(72) Inventors: Jin JANG, Seoul (KR); MD. HASNAT RABBI, Seoul (KR)

(21) Appl. No.: 18/656,755

(22) Filed: May 7, 2024

(30) Foreign Application Priority Data
May 8, 2023 (KR) 10-2023-0059251
Mar. 11, 2024 (KR) 10-2024-0034086

(51) Int. Cl. H01L 29/786; H01L 29/66

(52) U.S. Cl. CPC H01L 29/78693; H01L 29/66742

(57) ABSTRACT

A thin film transistor according to an embodiment may include a gate electrode disposed on a substrate; a semiconductor layer overlapping the gate electrode via a gate insulating layer interposed therebetween; and a source electrode and a drain electrode in contact with the semiconductor layer, the semiconductor layer may include an amorphous oxide semiconductor, and the semiconductor layer may include nanocrystalline dots.

### CROSS-REFERENCE TO RELATED APPLICATION

This application claims priority to and the benefit of Korean Patent Application No. 10-2023-0059251 and of Korean Patent Application No. 10-2024-0034086, the entire contents of which are incorporated herein by reference.

### BACKGROUND

### 1. Field

The present disclosure relates to a thin film transistor and a manufacturing method of the thin film transistor.

### 2. Description of the Related Art

A thin-film transistor is a switching device comprising a gate electrode supplied with a control signal, a source electrode supplied with a data voltage, and a drain electrode that outputs the data voltage as three terminals. In addition, this thin film transistor includes an active layer overlapping the gate electrode as a channel layer, and the active layer includes a semiconductor.

Meanwhile, with the development of a display technology including a thin film transistor, the development of a thin film transistor capable of high-speed driving is urgently needed. For this purpose, a technology using an oxide semiconductor with high electron mobility as an active layer has been developed, but a thin film transistor with improved performance is required to be used for high-speed operation.

In addition, since a manufacturing process of a thin film transistor with improved performance increases as the manufacturing process becomes more complicated, it is necessary to provide a thin film transistor manufacturing method that can simplify the manufacturing process to lower the manufacturing cost while maintaining high performance.

The above information disclosed in this Background section is only for enhancement of understanding of the background of the described technology, and therefore it may contain information that does not form the prior art that is already known in this country to a person of ordinary skill in the art.

### SUMMARY

Embodiments are to provide a thin film transistor that can maintain high performance while reducing manufacturing cost, and a thin film transistor manufacturing method.

However, the problems to be solved by the embodiments are not limited to the above-described problems and may be variously expanded in the range of the technical ideas included in the embodiments.

A thin film transistor according to an embodiment may include a gate electrode disposed on a substrate; a semiconductor layer overlapping the gate electrode via a gate insulating layer interposed therebetween; and a source electrode and a drain electrode in contact with the semiconductor layer, the semiconductor layer may include an amorphous oxide semiconductor, and the semiconductor layer may include nanocrystalline dots.

The semiconductor layer may include a channel region, and a source region and a drain region disposed in both sides of the channel region, the channel region may overlap the gate electrode, and the source region and the drain region may be connected to the source electrode and the drain electrode.

The semiconductor layer may include at least one of IGO (Indium-Gallium Oxide), IGZO (Indium-Gallium-Zinc Oxide), IZTO (Indium-Zinc-Tin Oxide), IGZTO (Indium-Gallium-Zinc-Tin Oxide).

The nanocrystalline dots of the semiconductor layer may include indium (In).

The nanocrystalline dots of the semiconductor layer may include indiumoxide (In₂O₃).

A ratio of the nanocrystalline dots to the semiconductor layer may be about 10% or less.

The ratio of the nanocrystalline dots to the semiconductor layer may be about less than 8%.

A mass density of the semiconductor layer may be about 5.5 g/cm³ to about 7.5 g/cm³.

The mass density of the semiconductor layer may be about 6 g/cm³ to about 7 g/cm³.

At least portion of the semiconductor layer may be treated with nitrous oxide (N₂O) plasma.

A thin film transistor manufacturing method according to an embodiment may comprise forming a gate electrode on a substrate; forming a gate insulation layer on the gate electrode; forming a semiconductor layer overlapping the gate electrode on the gate insulation layer; and forming a source electrode and a drain electrode that contact the semiconductor layer, the forming of the semiconductor layer may comprise spray coating a process solution including a metal precursor and a volatile solvent on the substrate, and a temperature of the substrate may be about 320° C. to about 390° C.

The spray coating may comprise preparing the process solution by mixing the metal precursor in the volatility solvent, spraying the process solution on the substrate together with a carrier gas; and evaporating the volatility solvent of the process solution.

The volatility solvent may include 2-methoxy ethanol (2-ME).

The forming of the semiconductor layer may repeat the spray coating several times.

The metal precursor may include indium (In).

The thin film transistor manufacturing method may further comprise treating at least portion of the semiconductor layer with nitrous oxide (N₂O) plasma.

The treating with nitrous oxide (N₂O) plasma is treating the semiconductor layer with nitrous oxide (N₂O) plasma by using the gate electrode as a mask.

According to the thin film transistor and the manufacturing method thereof according to the embodiment, it is possible to lower the manufacturing cost and maintain high performance.

It is apparent that the effect of this disclosure is not limited to the above-described effect, but may be variously extended within a range without departing from the spirit and scope of this disclosure.

### BRIEF DESCRIPTION OF THE DRAWINGS

FIG. 1 is a cross-sectional view of a thin film transistor according to an embodiment.

FIG. 2 is a cross-sectional view of a thin film transistor according to another embodiment.

FIG. 3 to FIG. 7 are cross-sectional views of a manufacturing method of a thin film transistor according to according to an embodiment.

FIG. 8 and FIG. 9 are cross-sectional views of a manufacturing method of a thin film transistor according to according to another embodiment.

FIG. 10 to FIG. 18 are electron microscope photos of a result of an experimental example.

FIG. 19 is a graph showing a result of the experimental example.

FIG. 20 to FIG. 23 are graphs showing a result of the experimental example.

FIG. 24 is an electron microscope photo of a result of an experimental example.

FIG. 25 and FIG. 26 are graphs showing a result of the experimental example.

### DETAILED DESCRIPTION

Hereinafter, with reference to the accompanying drawings, various embodiments will be described in detail such that a person of ordinary skill in the technical field to which this disclosure belongs can easily practice it. This disclosure may be implemented in several different forms and is not limited to the embodiments described herein.

In order to clearly explain the embodiments, parts irrelevant to the description are omitted, and the same reference sign is attached to the same or similar constituent elements throughout the specification.

In addition, the attached drawings are only for easy understanding of the embodiment disclosed in the present specification, and the technical ideas disclosed in this specification are not limited by the attached drawings, and all changes included in the spirit and technical range of this disclosure should be understood to include equivalents or substitutes.

In addition, since the size and thickness of each component shown in the drawing are arbitrarily indicated for convenience of explanation, the embodiments are not necessarily limited thereto. In the drawings, the thickness of layers, films, panels, regions, etc., are exaggerated for clarity. Further, in the drawing, for convenience of explanation, the thickness of some layers and regions is exaggerated.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, throughout the specification, the word “on” a target element will be understood to be positioned above or below the target element, and will not necessarily be understood to be positioned “at an upper side” based on an opposite to gravity direction.

In addition, unless explicitly described to the contrary, the word “comprise”, and variations such as “comprises” or “comprising”, will be understood to imply the inclusion of stated elements but not the exclusion of any other elements.

Further, throughout the specification, the phrase “on a plane” means viewing a target portion from the top, and the phrase “on a cross-section” means viewing a cross-section formed by vertically cutting a target portion from the side.

In addition, throughout the specification, when “connected to” in the entire specification, this does not only mean that two or more constituent elements are directly connected, but also means that two or more constituent elements are indirectly connected, physically connected, and electrically connected through other constituent elements, or being referred to by different names depending on the position or function, while being integral.

Hereinafter, various embodiments and variations will be described with reference to the accompanying drawings.

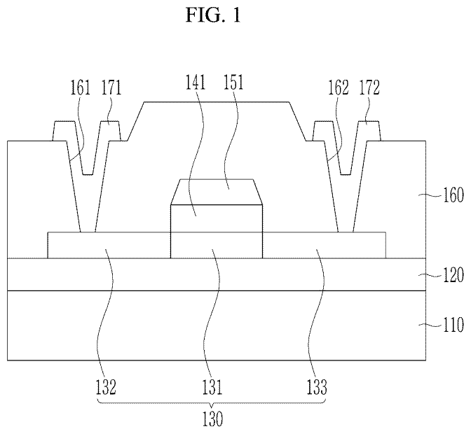

Referring to FIG. 1, a thin film transistor according to an embodiment will be described. FIG. 1 is a cross-sectional view of a thin film transistor according to an embodiment.

Referring to FIG. 1, a buffer layer 120 is disposed on a substrate 110. The buffer layer 120 may have a single-layered or multi-layered structure. In FIG. 1, the buffer layer 120 is illustrated as a single layer, but may be multi-layered according to an embodiment. The buffer layer 120 may include an organic insulating material or an inorganic insulating material. For example, the buffer layer 120 may include at least one of a silicon nitride (SiNx), a silicon oxide (SiOx), and a silicon oxynitride (SiOxNy).

A semiconductor layer 130 including a first region 131, a second region 132, and a third region 133 is positioned on the buffer layer 120.

The semiconductor layer 130 may include an amorphous oxide semiconductor.

The semiconductor layer 130 may include nanocrystalline dots.

The semiconductor layer 130 may include an oxide semiconducto. The oxide semiconductor may include at least one among a primary metal oxide such as indium (In) oxide, tin (Sn) oxide, or zinc (Zn) oxide, a binary metal oxide such as In—Zn-based oxides, Sn—Zn-based oxides, Al—Zn-based oxides, Zn—Mg-based oxides, Sn—Mg-based oxides, In—Mg-based oxides, or In—Ga-based oxides, a ternary metal oxide such as In—Ga—Zn-based oxides, In—Al—Zn-based oxides, In—Sn—Zn-based oxides, Sn—Ga—Zn-based oxides, Al—Ga—Zn-based oxides, Sn—Al—Zn-based oxides, In—Hf—Zn-based oxides, In—La—Zn-based oxides, In—Ce—Zn-based oxides, In—Pr—Zn-based oxides, In—Nd—Zn-based oxides, In—Sm—Zn-based oxides, In—Eu—Zn-based oxides, In—Gd—Zn-based oxides, In—Tb—Zn-based oxides, In—Dy—Zn-based oxides, In—Ho—Zn-based oxides, In—Er—Zn-based oxides, In—Tm—Zn-based oxides, In—Yb—Zn-based oxides, or In—Lu—Zn-based oxides, and a quaternary metal oxide such as In—Sn—Ga—Zn-based oxides, In—Hf—Ga—Zn-based oxides, In—Al—Ga—Zn-based oxides, In—Sn—Al—Zn-based oxides, In—Sn—Hf—Zn-based oxides, or In—Hf—Al—Zn-based oxides. For example, the oxide semiconductor may include Indium-Gallium Oxide (IGO) among the In—Ga-based oxide.

The semiconductor layer 130 may include at least one of IGO (Indium-Gallium Oxide), IGZO (Indium-Gallium-Zinc Oxide), IZTO (Indium-Zinc-Tin Oxide), IGZTO (Indium-Gallium-Zinc-Tin Oxide).

The nanocrystalline dots of the semiconductor layer 130 may include indium (In). More specifically, nanocrystalline dots of the semiconductor layer 130 may include indiumoxide (In₂O₃).

A ratio of the nanocrystalline dots to the semiconductor layer 130 may be about 10% or less, and more specifically, less than 8%.

The mass density of the semiconductor layer 130 may be about 5.5 g/cm³ to about 7.5 g/cm³, and more specifically, about 6 g/cm³ to about 7 g/cm³.

The oxygen vacancy related defect (O-vacancy (Vo) related defect) measured by X-ray photoelectron spectroscopy of the semiconductor layer 130 is about 30% or less, more specifically about 20% to about 30%, more specifically about 23%. to about 27%. The hydroxyl group (O—H) related defects measured by X-ray photoelectron spectroscopy of the semiconductor layer 130 may be less than about 4%, more specifically less than about 3%.

The surface roughness measured by an Atomic Force Microscope (AFM) of the semiconductor layer 130 may be about 0.25 nm to about 0.62 nm.

The first region 131 of the semiconductor layer 130 may be a channel region, and the second region 132 and the third region 133 of the semiconductor layer 130 may be a source region and a drain region.

The semiconductor layer 130 may be formed by a spray coating method. The solvent of the spray solution utilized in the spray method may include 2-methoxy ethanol (2-ME). The spray deposition process may be performed under a process temperature of about 300° C. or higher, more specifically, about 320° C. to about 390° C.

The nanocrystals of the semiconductor layer 130, as measured by a critical angle incidence X-ray diffraction (GI-XRD) method, may have a main peak value at a 2theta value of about 20° to about 25°, more specifically, about 23°.

At least a portion of the semiconductor layer 130 may be treated with nitrous oxide (N₂O) plasma. By doping at least portion of the semiconductor layer 130 by treating with nitrous oxide (N₂O) plasma, defects in the channels of the thin film transistor can be reduced and performance can be increased.

The gate insulating layer 141 is positioned on the first region 131 of the semiconductor layer 130. The gate insulating layer 141 may include an organic insulating material or an inorganic insulating material, for example, the gate insulating layer 141 may include at least among a silicon nitride, a silicon oxide, a silicon oxynitride, and tetraethyl orthosilicate (TEOS).

A gate electrode 151 is disposed on the gate insulating layer 141. The gate electrode 151 is disposed to overlap the first region 131 of the semiconductor layer 130, and the gate insulating layer 141 is disposed between the first region 131 of the semiconductor layer 130 and the gate electrode 151.

The gate electrode 151 may be a multilayer in which a metal film including any one of copper (Cu), a copper alloy, aluminum (AI), an aluminum alloy, molybdenum (Mo), and a molybdenum alloy is stacked.

A protective layer 160 is disposed on the semiconductor layer 130, the gate insulating layer 141, and the gate electrode 151. The protection layer 160 may include at least one of a silicon nitride, a silicon oxide, a silicon oxynitride, and tetraethyl orthosilicate (TEOS), and may be made of organic materials such as a polyacrylate resin, a polyimide resin, or laminated films of organic materials and inorganic materials.

The protection layer 160 has a first contact hole 161 overlapping the second region 132 of the semiconductor layer 130 and a second contact hole 162 overlapping the third region 133 of the semiconductor layer 130.

A source electrode 171 and a drain electrode 172 are disposed on the protection layer 160. The source electrode 171 may be connected to the second region 132 that is the source region of the semiconductor layer 130 by the first contact hole 161 of the protection layer 160, and the drain electrode 172 may be connected to the third region 133 that is the drain region of the semiconductor layer 130 by the second contact hole 162 of the protection layer 160.

The second region 132 that is a source region of the semiconductor layer 130 and the third region 133 that is a drain region of the semiconductor layer 130 may be treated with fluorine plasma.

For example, a fluorine plasma treatment may be performed on the semiconductor layer 130 with the gate electrode 151 as a mask.

By doping second region 132 that is a source region of the semiconductor layer 130 and the third region 133 that is a drain region of the semiconductor layer 130 with fluorine plasma, the efficiency of a channel of the thin film transistor may be increased by reducing a resistance and increasing a carrier concentration.

The source electrode 171 and the drain electrode 172 may include an aluminum-based metal, a silver-based metal, or a copper-based metal having low resistivity, for example, may have a triple-layer structure of a lower film including a refractory metal or alloys thereof, such as titanium, molybdenum, chromium, and tantalum; an interlayer film including aluminum-based metal, silver-based metal, and copper-based metal with low resistivity; and an upper layer including a refractory metal such as titanium, molybdenum, chromium, and tantalum.

The gate electrode 151, source electrode 171 and drain electrode 172 described above form a thin film transistor (TFT) together with the semiconductor layer 130, and the channel of the thin film transistor is formed in the first region 131 between the second region that is the source region of the semiconductors 131, 132, and 133 and the third region 133, which is the drain region.

Thin film transistors according to embodiments may have a threshold voltage (VTH) of about-0.7V to about 1.2V.

Thin film transistors according to embodiments may have a field-effect mobility (μ_{FE}) of about 14 cm²/V·s to about 29 cm²/V·s.

Thin film transistors according to embodiments may have a subthreshold swing (SS) of about 0.130V/dec. to about 0.240V/dec.

Thin film transistors according to embodiments may have an on-current (I_{ON}) of about 3.0 μA to about 5.5 μA under a gate voltage (V_{GS}) of about 20V and a drain voltage (V_{DS}) of about 0.1V.

Thin film transistors according to embodiments may have an on-off current ratio (I_{ON/OFF}) of about 1×10⁹ or greater, more specifically, about 1.8×10⁹ to about 3.4×10⁹.

Thin film transistors according to embodiments may have a threshold voltage shift (ΔV_{TH}) of about −4.9V to about −1.1V with a gate voltage (V_{GS}) change of ±20 V, at a temperature of about 60° C., for 1 hour, under a negative bias illumination stress under about 10,000 nits of white light.

Thin film transistors according to embodiments may withstand mechanical bending stresses up to a bending radius of about 1 mm.

According to the thin film transistors according to embodiments, the semiconductor layer 130 may include an oxide semiconductor, the semiconductor layer 130 may be formed by a spray coating method, and the semiconductor layer 130 may include nanocrystalline dots.

The method of forming oxide semiconductors by sputtering is performed in a high vacuum chamber, resulting in high manufacturing costs, and the method of forming oxide semiconductors by spin coating is not suitable for large-area substrate manufacturing due to uniformity issues.

However, according to the thin film transistor according to the embodiment, the oxide semiconductor layer is formed by a spray coating method, which enables the formation of a thin film transistor with excellent performance without increasing the manufacturing cost.

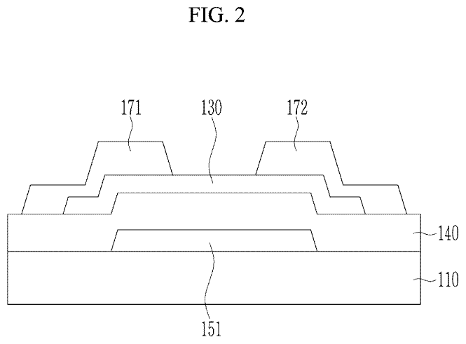

Referring to FIG. 2, a thin film transistor according to another embodiment will be described. FIG. 2 is a cross-sectional view of a thin film transistor according to another embodiment.

Referring to FIG. 2, a gate electrode 151 is disposed on a substrate 110, and a gate insulating layer 141 is disposed on the gate electrode 151.

The gate electrode 151 may be a multilayer in which a metal film including any one of copper (Cu), a copper alloy, aluminum (AI), an aluminum alloy, molybdenum (Mo), and a molybdenum alloy is stacked.

The gate insulating layer 141 may include an organic insulating material or an inorganic insulating material, for example, the gate insulating layer 141 may include at least among a silicon nitride, a silicon oxide, a silicon oxynitride, and tetraethyl orthosilicate (TEOS).

A semiconductor layer 130 including a first region 131, a second region 132, and a third region 133 is disposed on the gate insulating layer 141.

The semiconductor layer 130 may include an oxide semiconductor and the semiconductor layer 130 may include nanocrystalline dots. The oxide semiconductor may include at least one among a primary metal oxide such as indium (In) oxide, tin (Sn) oxide, or zinc (Zn) oxide, a binary metal oxide such as In—Zn-based oxides, Sn—Zn-based oxides, Al—Zn-based oxides, Zn—Mg-based oxides, Sn—Mg-based oxides, In—Mg-based oxides, or In—Ga-based oxides, a ternary metal oxide such as In—Ga—Zn-based oxides, In—Al—Zn-based oxides, In—Sn—Zn-based oxides, Sn—Ga—Zn-based oxides, Al—Ga—Zn-based oxides, Sn—Al—Zn-based oxides, In—Hf—Zn-based oxides, In—La—Zn-based oxides, In—Ce—Zn-based oxides, In—Pr—Zn-based oxides, In—Nd—Zn-based oxides, In—Sm—Zn-based oxides, In—Eu—Zn-based oxides, In—Gd—Zn-based oxides, In—Tb—Zn-based oxides, In—Dy—Zn-based oxides, In—Ho—Zn-based oxides, In—Er—Zn-based oxides, In—Tm—Zn-based oxides, In—Yb—Zn-based oxides, or In—Lu—Zn-based oxides, and a quaternary metal oxide such as In—Sn—Ga—Zn-based oxides, In—Hf—Ga—Zn-based oxides, In—Al—Ga—Zn-based oxides, In—Sn—Al—Zn-based oxides, In—Sn—Hf—Zn-based oxides, or In—Hf—Al—Zn-based oxides.

The semiconductor layer 130 may include at least one of IGO (Indium-Gallium Oxide), IGZO (Indium-Gallium-Zinc Oxide), IZTO (Indium-Zinc-Tin Oxide), IGZTO (Indium-Gallium-Zinc-Tin Oxide).

The nanocrystalline dots of the semiconductor layer 130 may include indium (In). More specifically, nanocrystalline dots of the semiconductor layer 130 may include indiumoxide (In₂O₃).

A ratio of the nanocrystalline dots to the semiconductor layer 130 may be about 10% or less, and more specifically, less than 8%.

The mass density of the semiconductor layer 130 may be about 5.5 g/cm³ to about 7.5 g/cm³, and more specifically, about 6 g/cm³ to about 7 g/cm³.

The oxygen vacancy related defect (O-vacancy (Vo) related defect) measured by X-ray photoelectron spectroscopy of the semiconductor layer 130 is about 30% or less, more specifically about 20% to about 30%, more specifically about 23%. to about 27%. The hydroxyl group (O—H) related defects measured by X-ray photoelectron spectroscopy of the semiconductor layer 130 may be less than about 4%, more specifically less than about 3%.

The surface roughness measured by an Atomic Force Microscope (AFM) of the semiconductor layer 130 may be about 0.25 nm to about 0.62 nm.

The first region 131 of the semiconductor layer 130 may be a channel region, and the second region 132 and the third region 133 of the semiconductor layer 130 may be a source region and a drain region.

The semiconductor layer 130 may be formed by a spray coating method. The solvent of the spray solution utilized in the spray method may include 2-methoxy ethanol (2-ME). The spray deposition process may be performed under a process temperature of about 300° C. or higher, more specifically, about 320° C. to about 390° C.

The nanocrystals of the semiconductor layer 130, as measured by a critical angle incidence X-ray diffraction (GI-XRD) method, may have a main peak value at a 2theta value of about 20° to about 25°, more specifically, about 23°.

At least a portion of the semiconductor layer 130 may be treated with nitrous oxide (N₂O) plasma. By doping at least portion of the semiconductor layer 130 by treating with nitrous oxide (N₂O) plasma, defects in the channels of the thin film transistor can be reduced and performance can be increased.

The second region 132 that is a source region of the semiconductor layer 130 and the third region 133 that is a drain region of the semiconductor layer 130 may be treated with fluorine plasma.

By doping second region 132 that is a source region of the semiconductor layer 130 and the third region 133 that is a drain region of the semiconductor layer 130 with fluorine plasma, the efficiency of a channel of the thin film transistor may be increased by reducing a resistance and increasing a carrier concentration.

A source electrode 171 is disposed on the second region 132 that is the source region of the semiconductor layer 130, and a drain electrode 172 is disposed on the third region 133 that is the drain region of the semiconductor layer 130.

The source electrode 171 and the drain electrode 172 may include an aluminum-based metal, a silver-based metal, or a copper-based metal having low resistivity, for example, may have a triple-layer structure of a lower film including a refractory metal or alloys thereof, such as titanium, molybdenum, chromium, and tantalum; an interlayer film including aluminum-based metal, silver-based metal, and copper-based metal with low resistivity; and an upper layer including a refractory metal such as titanium, molybdenum, chromium, and tantalum.

The gate electrode 151, source electrode 171 and drain electrode 172 form a thin film transistor (TFT) together with the semiconductor layer 130, and the channel of the thin film transistor is formed in the first region 131 between the second region that is the source region of the semiconductors 131, 132, and 133 and the third region 133, which is the drain region.

According to the thin film transistor according to the embodiment, the semiconductor layer 130 may include an oxide semiconductor, and the semiconductor layer 130 may be formed by a spray coating method. Accordingly, the performance of the transistor may be increased without complicating the manufacturing process, and thereby without increasing the manufacturing cost.

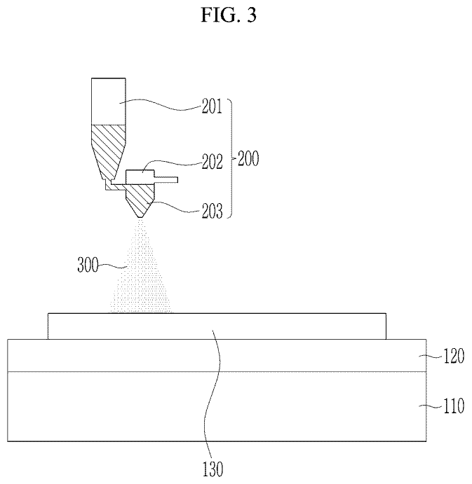

Referring to FIG. 3 to FIG. 5 along with FIG. 1, a manufacturing method of a thin film transistor according to an embodiment will be described. FIG. 3 to FIG. 5 are cross-sectional views showing a manufacturing method of a thin film transistor according to an embodiment.

As shown in FIG. 3, a buffer layer 120 is deposited on a substrate 110, and a semiconductor layer 130 is formed on the buffer layer 120.

A semiconductor layer 130 may be deposited by a spray coating method with using a spray coating device 200.

The spray coating device 200 may include a solution supply portion 201 accommodating a spray solution, a gas supply portion 202, and a nozzle 203.

A process for forming the semiconductor layer 130 may include preparing a process solution by mixing a metal precursor included in an oxide semiconductor of the semiconductor layer 140 and a stabilizer in a volatile solvent; spraying the process solution on the substrate 110 through the nozzle 203 together with the carrier gas such as nitrogen supplied through the gas supply portion 202; and evaporating the volatile solvent contained in the process solution. Further, the step of spraying the process solution onto the substrate 110 and evaporating the volatile solvent contained in the process solution may be repeated several times.

The forming of the semiconductor layer 140 may be performed under a process temperature of about 300° C. or higher, more specifically, about 320° C. to about 390° C.

By performing the spray coating process at a process temperature of the substrate of at least 300° C., and more specifically at a temperature of about 320° C. to about 390° C., the volatile solvent can be evaporated just before droplets of the volatile solvent contact the substrate. Accordingly, a thin film of uniform semiconductor layer 130 can be deposited.

The semiconductor layer 130 may include at least one of Indium-Gallium Oxide (IGO), Indium-Gallium-Zinc Oxide (IGZO), Indium-Zinc-Tin Oxide (IZTO), and Indium-Gallium-Zinc-Tin Oxide (IGZTO).

The solvent of the spray solution may include 2-methoxy ethanol (2-ME).

As the spray coating process is repeated, the thickness of the semiconductor layer 130 may become thicker.

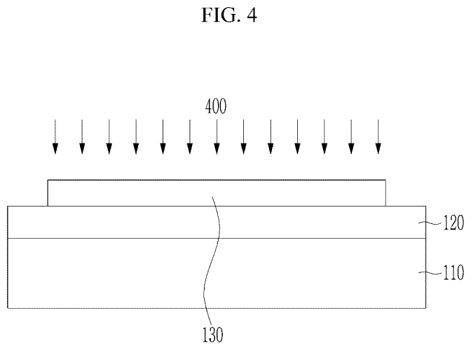

As shown in FIG. 4, the semiconductor layer 130 deposited by the spray coating process may be treated with nitrous oxide (N₂O) plasma. By doping at least portion of the semiconductor layer 130 by treating with nitrous oxide (N₂O) plasma, defects in the channels of the thin film transistor can be reduced and performance can be increased.

The semiconductor layer 130 may include an amorphous oxide semiconductor.

The semiconductor layer 130 may include nanocrystalline dots.

The nanocrystalline dots of the semiconductor layer 130 may include indium (In). More specifically, nanocrystalline dots of the semiconductor layer 130 may include indiumoxide (In₂O₃).

A ratio of the nanocrystalline dots to the semiconductor layer 130 may be about 10% or less, and more specifically, less than 8%.

The mass density of the semiconductor layer 130 may be about 5.5 g/cm³ to about 7.5 g/cm³, and more specifically, about 6 g/cm³ to about 7 g/cm³.

The oxygen vacancy related defect (O-vacancy (Vo) related defect) measured by X-ray photoelectron spectroscopy of the semiconductor layer 130 is about 30% or less, more specifically about 20% to about 30%, more specifically about 23%. to about 27%. The hydroxyl group (O—H) related defects measured by X-ray photoelectron spectroscopy of the semiconductor layer 130 may be less than about 4%, more specifically less than about 3%.

The surface roughness measured by an Atomic Force Microscope (AFM) of the semiconductor layer 130 may be about 0.25 nm to about 0.62 nm.

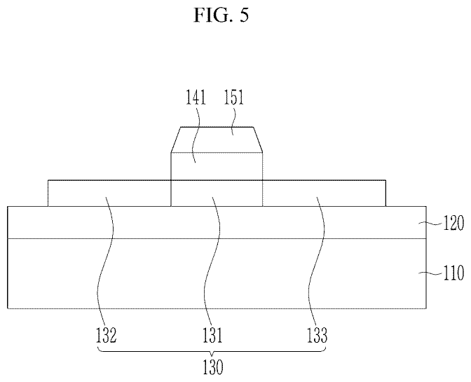

As shown in FIG. 5, a gate insulating layer 141 and a gate electrode 151 may be formed to overlap the first region of the semiconductor layer 130.

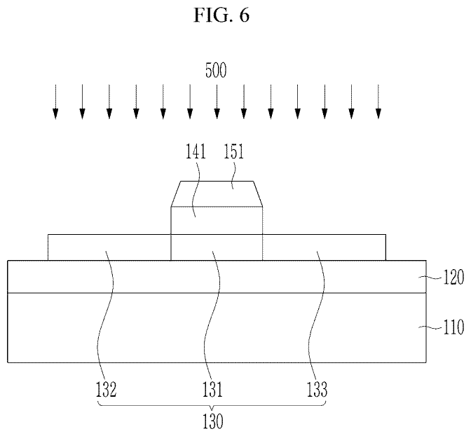

As shown in FIG. 6, the semiconductor layer 130 may be treated with fluorine plasma (500) by using the gate insulating layer 141 and the gate electrode 151 as a mask, and the second region 132 and the third region 133 of the semiconductor layer 130 may be doped with impurities of fluorine through the fluorine plasma treatment 500.

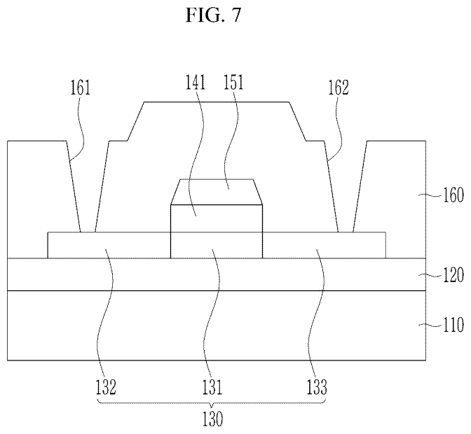

As shown in FIG. 7, a protective layer 160 may be deposited and a first contact hole 161 and a second contact hole 162 may be formed in the protective layer 160. Then a source electrode 171 connected to the second region 132 through the first contact hole 161 and a drain electrode 172 connected to the third region 133 of the semiconductor layer 130 may be formed to form the thin film transistor shown in FIG. 1.

The thin film transistor formed by the manufacturing method of the thin film transistor according to the embodiment may have a threshold voltage (VTH) of about −0.7 V to about 1.2 V.

The thin film transistor formed by the manufacturing method of the thin film transistor according to the embodiment may have a field-effect mobility (μ_{FE}) of about 14 cm²/V·s to about 29 cm²/V·s.

The thin film transistor formed by the manufacturing method of the thin film transistor according to the embodiment may have a subthreshold swing (SS) of about 0.130V/dec. to about 0.240V/dec.

The thin film transistor formed by the manufacturing method of the thin film transistor according to the embodiment may have an on-current (I_{ON}) of about 3.0 μA to about 5.5 μA under a gate voltage (V_{GS}) of about 20V and a drain voltage (V_{DS}) of about 0.1V.

The thin film transistor formed by the manufacturing method of the thin film transistor according to the embodiment may have an on-off current ratio (I_{ON/OFF}) of about 1×10⁹ or greater, more specifically, about 1.8×10⁹ to about 3.4×10⁹.

The thin film transistor formed by the manufacturing method of the thin film transistor according to the embodiment may have a threshold voltage shift (ΔV_{TH}) of about −4.9 V to about −1.1 V with a gate voltage (V_{GS}) change of ±20 V, at a temperature of about 60° C., for 1 hour, under a negative bias illumination stress under about 10,000 nits of white light.

The thin film transistor formed by the manufacturing method of the thin film transistor according to the embodiment may withstand mechanical bending stresses up to a bending radius of about 1 mm.

According to the manufacturing method of the thin film transistor of the embodiment, by repeating the processes of spraying the solution in which the precursor of the material included in the oxide semiconductors and the stabilizer are mixed with the volatile solvent with the carrier gas such as nitrogen and then evaporating the volatile solvent under the temperature of about 300° C. or higher, more specifically under the temperature of about 320° C. to about 390° C. to form the semiconductor thin film, the oxide semiconductor layer 130 including the nanocrystalline dots may be formed.

The method of forming oxide semiconductors by sputtering is performed in a high vacuum chamber, resulting in high manufacturing costs, and the method of forming oxide semiconductors by spin coating is not suitable for large-area substrate manufacturing due to uniformity issues.

However, according to the thin film transistor according to the embodiment, the oxide semiconductor layer is formed by a spray coating method, which enables the formation of a thin film transistor with excellent performance without increasing the manufacturing cost.

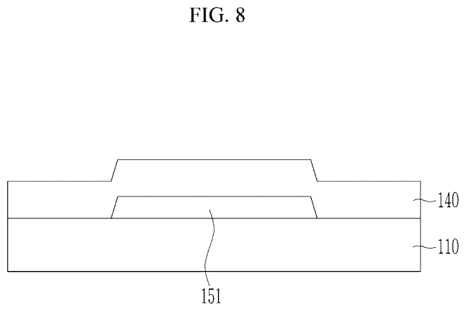

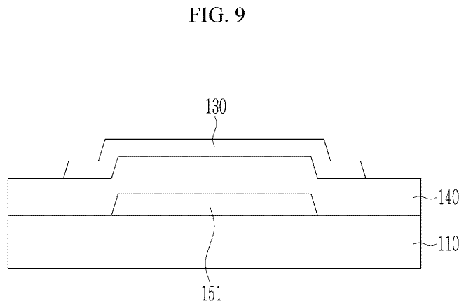

Referring to FIG. 8 and FIG. 9 with FIG. 2, a manufacturing method of a thin film transistor according to another embodiment will be described. FIG. 8 and FIG. 9 are cross-sectional views showing a manufacturing method of a thin film transistor according to another embodiment.

As shown in FIG. 8, a gate electrode 151 may be formed on a substrate 110, and a gate insulating layer 141 may be formed on the gate electrode 151.

As shown in FIG. 9, a semiconductor layer 130 may be deposited on the gate insulating layer 141 by a spray coating method under the temperature of about 300° C. or higher, more specifically under the temperature of about 320° C. to about 390° C.

A process for forming the semiconductor layer 130 may include preparing a process solution by mixing a metal precursor included in an oxide semiconductor of the semiconductor layer 140 and a stabilizer in a volatile solvent; spraying the process solution on the substrate 110 through the nozzle 203 together with the carrier gas such as nitrogen supplied through the gas supply portion 202; and evaporating the volatile solvent contained in the process solution. Further, the step of spraying the process solution onto the substrate 110 and evaporating the volatile solvent contained in the process solution may be repeated several times.

The semiconductor layer 130 may include at least one of Indium-Gallium Oxide (IGO), Indium-Gallium-Zinc Oxide (IGZO), Indium-Zinc-Tin Oxide (IZTO), and Indium-Gallium-Zinc-Tin Oxide (IGZTO).

The solvent of the spray solution may include 2-methoxy ethanol (2-ME).

As the spray coating process is repeated, the thickness of the semiconductor layer 130 may become thicker.

The semiconductor layer 130 deposited by the spray coating process may be treated with nitrous oxide (N₂O) plasma. By doping at least portion of the semiconductor layer 130 by treating with nitrous oxide (N₂O) plasma, defects in the channels of the thin film transistor can be reduced and performance can be increased.

The semiconductor layer 130 may include an amorphous oxide semiconductor.

The semiconductor layer 130 may include nanocrystalline dots.

The nanocrystalline dots of the semiconductor layer 130 may include indium (In). More specifically, nanocrystalline dots of the semiconductor layer 130 may include indiumoxide (In₂O₃).

A ratio of the nanocrystalline dots to the semiconductor layer 130 may be about 10% or less, and more specifically, less than 8%.

The mass density of the semiconductor layer 130 may be about 5.5 g/cm³ to about 7.5 g/cm³, and more specifically, about 6 g/cm³ to about 7 g/cm³.

The oxygen vacancy related defect (O-vacancy (Vo) related defect) measured by X-ray photoelectron spectroscopy of the semiconductor layer 130 is about 30% or less, more specifically about 20% to about 30%, more specifically about 23%. to about 27%. The hydroxyl group (O—H) related defects measured by X-ray photoelectron spectroscopy of the semiconductor layer 130 may be less than about 4%, more specifically less than about 3%.

The surface roughness measured by an Atomic Force Microscope (AFM) of the semiconductor layer 130 may be about 0.25 nm to about 0.62 nm.

The second region 132 and the third region 133 of the semiconductor layer 130 may be treated with fluorine plasma, and the second region 132 and the third region 133 of the semiconductor layer 130 may be doped with impurities of fluorine through the fluorine plasma treatment.

After the semiconductor layer 130 including an oxide semiconductor layer with nanocrystalline dots is formed by the spray coating process and a source electrode 171 and a drain electrode 172 are formed on the second region 132 and the third region 133 of the semiconductor layer 130 to form the thin film transistor shown in FIG. 2.

The thin film transistor formed by the manufacturing method of the thin film transistor according to the embodiment may have a threshold voltage (VTH) of about −0.7 V to about 1.2 V.

The thin film transistor formed by the manufacturing method of the thin film transistor according to the embodiment may have a field-effect mobility (μ_{FE}) of about 14 cm²/V·s to about 29 cm²/V·s.

The thin film transistor formed by the manufacturing method of the thin film transistor according to the embodiment may have a subthreshold swing (SS) of about 0.130V/dec. to about 0.240V/dec.

The thin film transistor formed by the manufacturing method of the thin film transistor according to the embodiment may have an on-current (I_{ON}) of about 3.0 μA to about 5.5 μA under a gate voltage (V_{GS}) of about 20V and a drain voltage (V_{DS}) of about 0.1V.

The thin film transistor formed by the manufacturing method of the thin film transistor according to the embodiment may have an on-off current ratio (I_{ON/OFF}) of about 1×10⁹ or greater, more specifically, about 1.8×10⁹ to about 3.4×10⁹.

The thin film transistor formed by the manufacturing method of the thin film transistor according to the embodiment may have a threshold voltage shift (ΔV_{TH}) of about −4.9 V to about −1.1 V with a gate voltage (V_{GS}) change of ±20 V, at a temperature of about 60° C., for 1 hour, under a negative bias illumination stress under about 10,000 nits of white light.

The thin film transistor formed by the manufacturing method of the thin film transistor according to the embodiment may withstand mechanical bending stresses up to a bending radius of about 1 mm.

According to the thin film transistor according to the embodiment, the oxide semiconductor layer is formed by a spray coating method, which enables the formation of a thin film transistor with excellent performance without increasing the manufacturing cost.

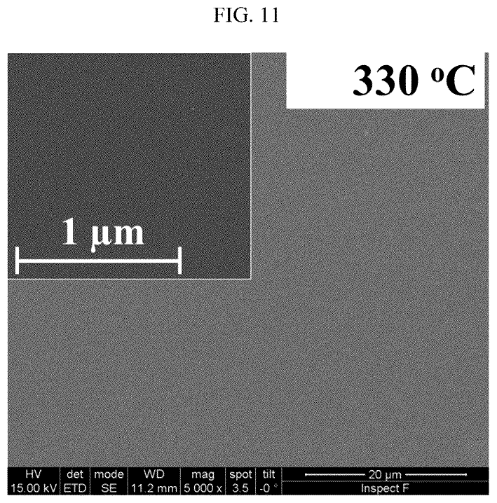

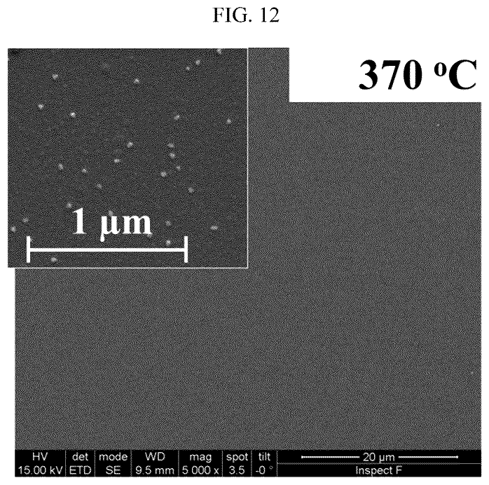

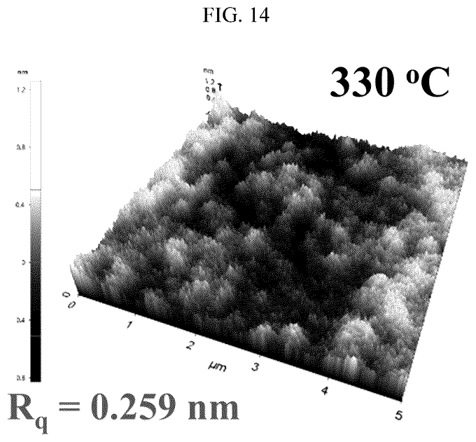

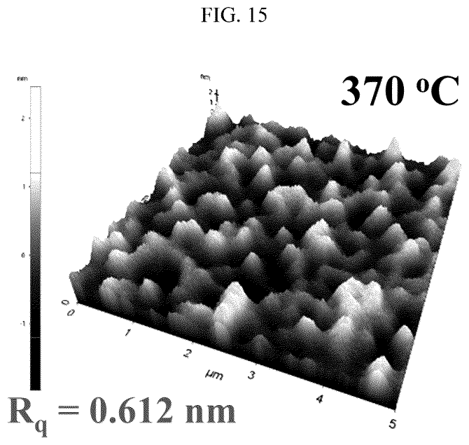

Referring to FIG. 8 to FIG. 16, a result of an Experimental Example will be described. FIG. 8 to FIG. 16 are electron micrographs illustrating the results of the Experimental Example.

In the present experimental example, an oxide semiconductor layer was deposited on the substrate by spray coating method in the first case where the temperature of the substrate was maintained at about 290° C., in the second case where the temperature of the substrate was maintained at about 330° C., and in the third case where the temperature of the substrate was maintained at about 370° C., and the results were measured by electron micrographs.

More specifically, an IGO solution with In:Ga=1:1 was synthesized in an N₂ glove box and IGO thin films were deposited on glass and PI/glass substrates by spray coating method. The distance from the spray nozzle to the substrate surface was about 10 cm, the N₂ gas pressure was about 0.2 MPa. A flow rate of 0.05 ml/sec at a nozzle speed of about 6 cm/sec was maintained over a 15 cm×15 cm substrate.

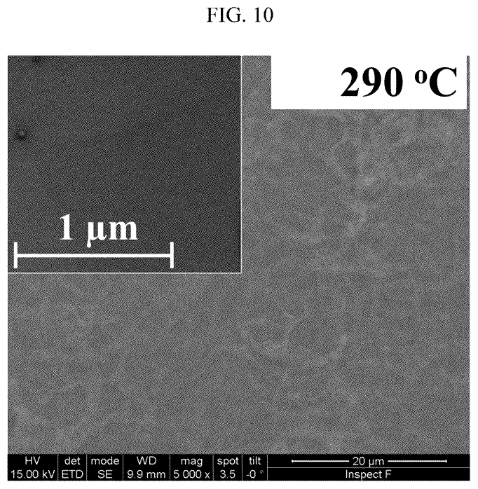

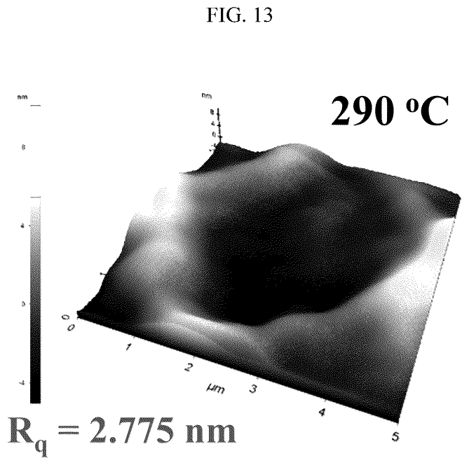

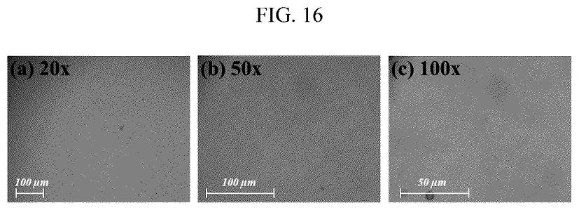

FIG. 10 to FIG. 12 illustrate SEM and optical micrographs of the deposited oxide semiconductor layers in the first case, the second case, and the third case, FIG. 13 to FIG. 15 illustrate AFM topographic images of the deposited oxide semiconductor layers in the first case, the second case, and the third case, and FIG. 16 to FIG. 18 illustrate optical micrographs at 20×, 50×, and 100× magnification in the first case, the second case, and the third case.

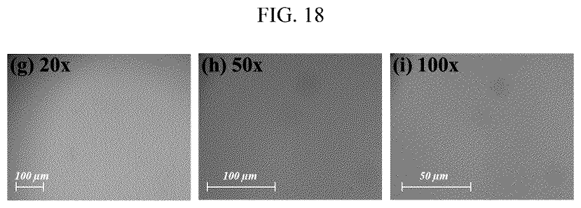

FIG. 10 to referring to FIG. 18, the oxide semiconductor thin films deposited at about 290° C. had some coffee rings and this indicated that nucleation boiling was dominant. In this case, it can be seen that the spray droplets were deposited on the substrate before the solvent evaporates. On the other hand, the oxide semiconductor thin films deposited at about 330° C. and about 370° C. had a smooth surface morphology without coffee rings respectively, and this indicated that the oxide semiconductor thin films were deposited by Leiden Frost-Dominated Boiling (LFDB) film growth. In this case, it can be seen that precursor diffusions were increased in the substrate and the lateral growth of the film was induced on the substrate. In addition, it can be seen that the oxide semiconductor thin films deposited at about 330° C. and about 370° C. were found to have high-density, and this indicated that the solvent was evaporated before reaching the substrate, resulting in the enhanced LFDB growth without substrate wetting.

In addition, it was found that the surface roughness of the oxide semiconductor thin film is about 2.78 nm when it was deposited at about 290° C. and decreased to about 0.26 nm when it was deposited at about 330° C., but increased to 0.61 nm when it was deposited at about 370° C. This is due to the generation of nanocrystalline dots when it was deposited at about 370° C.

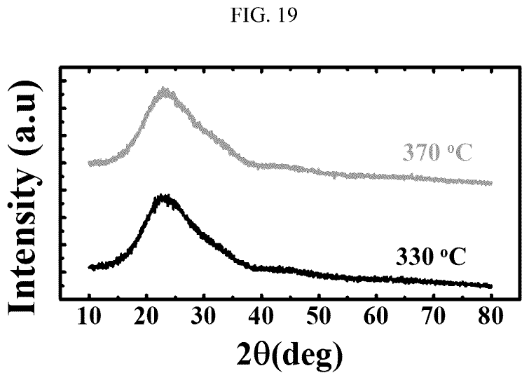

Referring to FIG. 19, another Experimental Example will be described. FIG. 19 is a graph depicting the results of another Experimental Example.

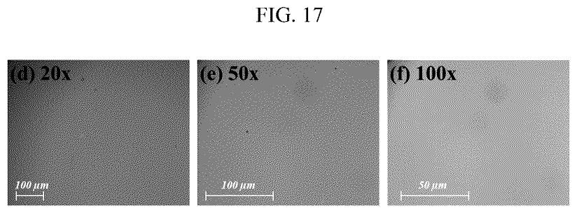

In this experimental example, a-IGO films were deposited by spray coating method at deposition temperatures of about 330° C. and about 370° C., respectively, and the grazing incidence X-ray diffraction (GI-XRD) results are shown in FIG. 17.

Referring to FIG. 19, the grazing incidence X-ray diffraction (GI-XRD) result showed a main peak at a 2-theta (20) value of about 20 degrees to about 25 degrees.

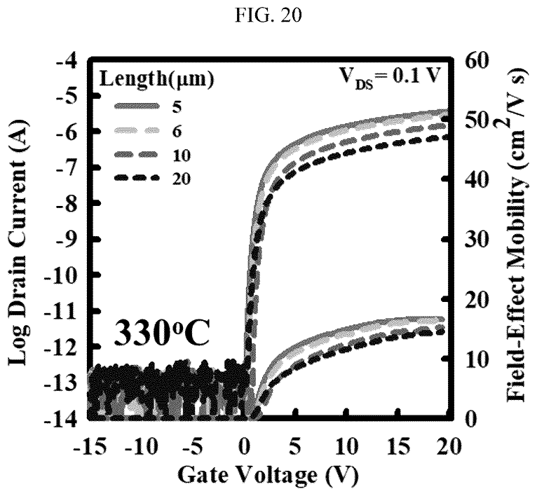

Referring to FIG. 20 to FIG. 23 with Table 1, another Experimental Example will be described. FIG. 20 to FIG. 23 are graphs depicting the results of another Experimental Example.

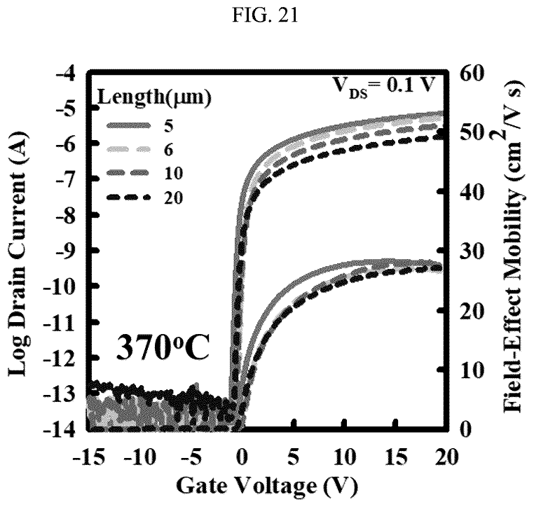

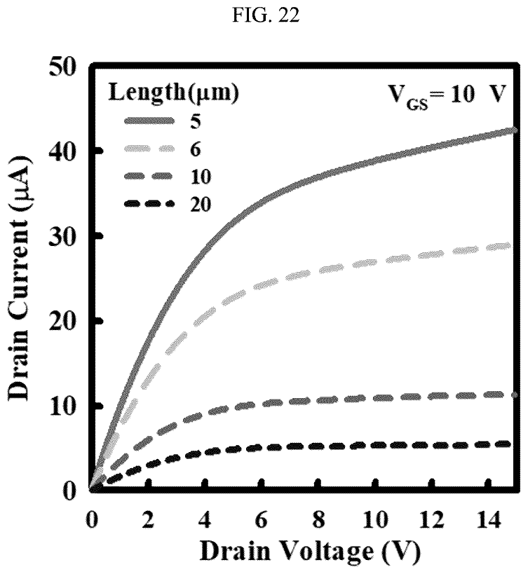

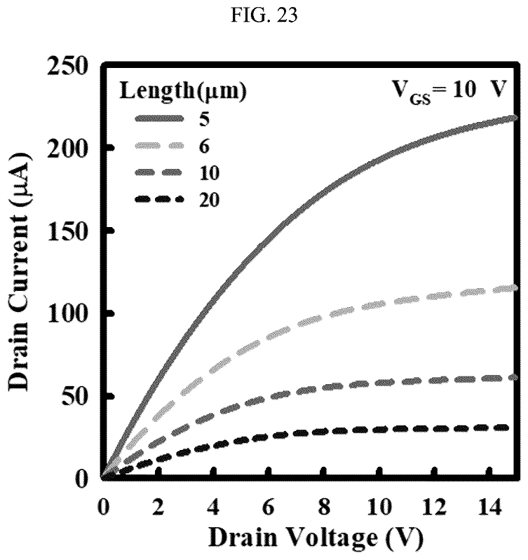

In the present experimental example, thin film transistors comprising a-IGO film deposited by a spray coating method at a deposition temperature of about 330° C. and about 370° C. by varying the channel length were formed, the performance of the formed thin film transistor was measured, the results were shown in FIG. 20 to FIG. 23, and the results were summarized in Table 1. FIG. 20 and FIG. 21 depict the results of the transfer characteristics of a thin film transistor formed at about 330° C. and about 370° C., respectively, and FIG. 22 and FIG. 23 depict the output characteristics of a thin film transistor formed at about 330° C. and about 370° C., respectively.

TABLE 1

| T_{depo.}(° C.) | Length (μm) | 5 | 6 | 10 | 20 |
|---|---|---|---|---|---|
| 330 | μ_{FE} (cm²/V · s) | 16.64 | 16.46 | 15.17 | 14.49 |
| | V_{TH} (V) | 0.6 | 0.8 | 1.2 | 0.7 |
| | SS (V/dec.) | 0.173 | 0.188 | 0.200 | 0.234 |
| | μ_{SAT} cm²/V · s) | 26.87 | 24.79 | 18.28 | 16.74 |
| 370 | μ_{FE} (cm²/V · s) | 28.19 | 26.96 | 27.95 | 27.11 |
| | V_{TH} (V) | −0.7 | −0.2 | −0.2 | −0.4 |
| | SS (V/dec.) | 0.132 | 0.136 | 0.152 | 0.157 |
| | μ_{SAT} (cm²/V · s) | 39.14 | 32.92 | 32.32 | 28.79 |

In this experimental example, the channel lengths of the transistors were about 5 μm, about 6 μm, about 10 μm, and about 20 μm while keeping the channel width of the transistors at about 20 μm, and the transfer characteristics and output characteristics of the transistors were measured. The transfer characteristics were measured under a variable gate voltage (V_{GS}) swinging from about-15V to about 20V and a drain voltage (V_{DS}) of about 0.1V. The output characteristics were measured under a constant gate voltage (V_{GS}) of about 10V and a variable drain voltage (V_{DS}) of about 0V to about 15V.

Referring to Table 1 with FIG. 20 to FIG. 23, according to the thin film transistor and the manufacturing method thereof according to the embodiments, it may be seen that the thin film transistors are capable of acting as a switching element and the characteristics thereof are excellent.

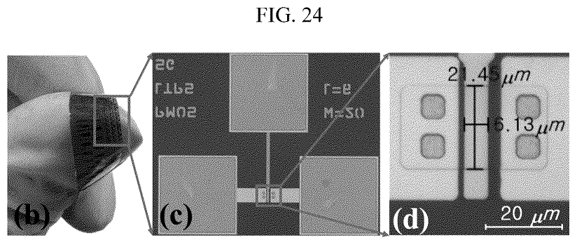

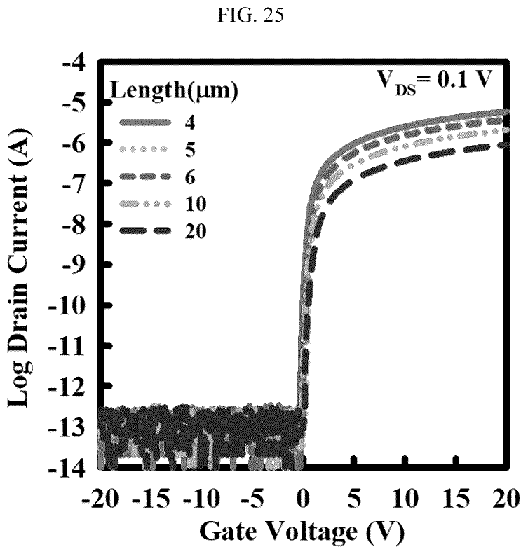

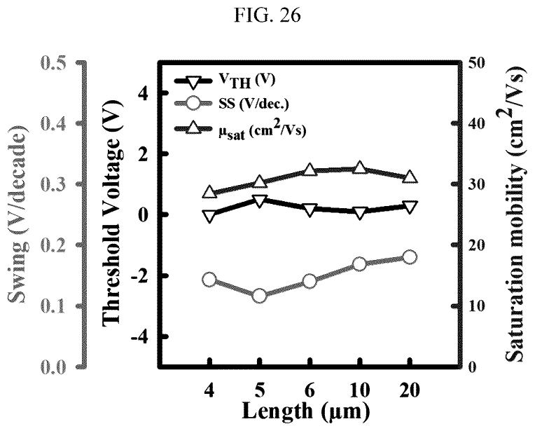

Referring to FIG. 24 to FIG. 26, another Experimental Example will be described. FIG. 24 is an electron microscope of another Experimental Example. FIG. 25 and FIG. 26 are graphs depicting results of another Experimental Example.

In the present experimental example, thin film transistors comprising a-IGO film deposited by a spray coating method at a deposition temperature of about 330° C. and about 370° C. by varying the channel length were formed, the performance of the formed thin film transistor was measured.

Referring to FIG. 24 to FIG. 26, according to the thin film transistor and the manufacturing method thereof according to the embodiments, it may be seen that the thin film transistors are capable of acting as a switching element and the characteristics thereof are excellent.

While this disclosure has been described in connection with what is presently considered to be practical embodiments, it is to be understood that the invention is not limited to the disclosed embodiments. On the contrary, it is intended to cover various modifications and equivalent arrangements included within the spirit and scope of the appended claims.

### DESCRIPTION OF SYMBOLS

110: substrate
120: buffer layer
130: semiconductor layer
141: gate insulating layer
151: gate electrode
160: protective layer
161, 162: contact hole
171: source electrode
172: drain electrode

What is claimed is:

1. A thin film transistor comprising:
a gate electrode disposed on a substrate;
a semiconductor layer overlapping the gate electrode via a gate insulating layer interposed therebetween; and
a source electrode and a drain electrode in contact with the semiconductor layer,
wherein the semiconductor layer includes an amorphous oxide semiconductor, and
wherein the semiconductor layer includes nanocrystalline dots.

2. The thin film transistor of claim 1, wherein:
the semiconductor layer includes a channel region, and a source region and a drain region disposed in both sides of the channel region,
the channel region overlaps the gate electrode, and
the source region and the drain region are connected to the source electrode and the drain electrode.

3. The thin film transistor of claim 1, wherein:
the semiconductor layer includes at least one of IGO (Indium-Gallium Oxide), IGZO (Indium-Gallium-Zinc Oxide), IZTO (Indium-Zinc-Tin Oxide), IGZTO (Indium-Gallium-Zinc-Tin Oxide).

4. The thin film transistor of claim 3, wherein:
the nanocrystalline dots of the semiconductor layer include indium (In).

5. The thin film transistor of claim 4, wherein:
the nanocrystalline dots of the semiconductor layer include indiumoxide (In₂O₃).

6. The thin film transistor of claim 3, wherein:
a ratio of the nanocrystalline dots to the semiconductor layer is about 10% or less.

7. The thin film transistor of claim 6, wherein:
the ratio of the nanocrystalline dots to the semiconductor layer is less than 8%.

8. The thin film transistor of claim 1, wherein:
a mass density of the semiconductor layer is about 5.5 g/cm³ to about 7.5 g/cm³.

9. The thin film transistor of claim 8, wherein:
the mass density of the semiconductor layer is about 6 g/cm³ to about 7 g/cm³.

10. The thin film transistor of claim 1, wherein:
at least portion of the semiconductor layer is treated with nitrous oxide (N₂O) plasma.

11. A thin film transistor manufacturing method comprising:
forming a gate electrode on a substrate;
forming a gate insulation layer on the gate electrode;
forming a semiconductor layer overlapping the gate electrode on the gate insulation layer; and
forming a source electrode and a drain electrode that contact the semiconductor layer,
wherein the forming of the semiconductor layer comprises spray coating a process solution including a metal precursor and a volatile solvent on the substrate, and
wherein a temperature of the substrate is about 320° C. to about 390° C.

12. The thin film transistor manufacturing method of claim 11, wherein:
the spray coating comprises:
preparing the process solution by mixing the metal precursor in the volatility solvent;
spraying the process solution on the substrate together with a carrier gas; and
evaporating the volatility solvent of the process solution.

13. The thin film transistor manufacturing method of claim 12, wherein:
the volatility solvent includes 2-methoxy ethanol (2-ME).

14. The thin film transistor manufacturing method of claim 11, wherein:
the forming of the semiconductor layer repeats the spray coating several times.

15. The thin film transistor manufacturing method of claim 11, wherein:
the metal precursor includes indium (In).

16. The thin film transistor manufacturing method of claim 15, wherein:
the semiconductor layer includes at least one of IGO (Indium-Gallium Oxide), IGZO (Indium-Gallium-Zinc Oxide), IZTO (Indium-Zinc-Tin Oxide), IGZTO (Indium-Gallium-Zinc-Tin Oxide).

17. The thin film transistor manufacturing method of claim 11, further comprising:
treating at least portion of the semiconductor layer with nitrous oxide (N₂O) plasma.

18. The thin film transistor manufacturing method of claim 17, wherein:
the treating with nitrous oxide (N₂O) plasma is treating the semiconductor layer with nitrous oxide (N₂O) plasma by using the gate electrode as a mask.
